(19) United States
(12) Patent Application Publication
(10) Pub. No.: US 2009/0242887 A1
(43) Pub. Date: Oct. 1, 2009

(54) Display Substrate Having a Transparent Conductive Layer Made of Zinc Oxide and Manufacturing Method Thereof

(75) Inventors: Tetsuya YAMAMOTO, Kochi (JP); Naoki YAMAMOTO, Kochi (JP); Hisao MAKINO, Kochi (JP); Akira UJIHARA, Tokyo (JP); Yoshinori HIRASHIMA, Tokyo (JP); Hiroaki IWAOKA, Tokyo (JP); Hisashi AOKI, Tokyo (JP); Hitoshi HOKARI, Tokyo (JP); Motohiko YOSHIDA, Tokyo (JP)

Correspondence Address: MASAO YOSHIMURA, CHEN YOSHIMURA LLP, 333 W. El Camino Real, Suite 380, Sunnyvale, CA, 94087, US

(73) Assignees: CASIO COMPUTER CO., LTD., Tokyo (JP); Kochi University of Technology, Kochi (JP)

(21) Appl. No.: 12/413,318

(22) Filed: Mar. 27, 2009

(30) Foreign Application Priority Data
Mar. 31, 2008 (JP) 2008-094411
Mar. 9, 2009 (JP) 2009-055755

(51) Int. Cl. H01L 33/00; H01L 21/28; C23C 14/32

(52) U.S. Cl. 257/59; 438/29; 204/192.25; 257/E33.053; 257/E21.158

(57) ABSTRACT

A display substrate is disclosed comprising: a supporting substrate; an organic resin layer formed on the supporting substrate; and a transparent electrode formed on the organic resin layer, wherein the transparent electrode includes: a first layer containing a zinc oxide and formed in close contact with the organic resin layer; and a second layer containing a zinc oxide and which has a thickness thicker than a thickness of the first layer and is formed on the first layer, wherein the first layer is deposited by either one of a DC sputtering and a DC magnetron sputtering, and the second layer is deposited by any one of a radio frequency sputtering, a radio frequency magnetron sputtering, a radio frequency superimposing a DC sputtering, and a radio frequency superimposing a DC magnetron sputtering, and the display substrate is available, for example, as the substrate having a transparent electrode for counter electrode of liquid crystal display device.

This application is based upon and claims the benefit of Japanese Patent Application No. 2008-094411, filed in Japan on Mar. 31, 2008, and Japanese Patent Application No. 2009-055755, filed in Japan on Mar. 9, 2009, both of which are hereby incorporated by reference in their entries.

### BACKGROUND OF THE INVENTION

1. Field of the Invention

The present invention relates to a display substrate comprising a transparent conductive layer, which uses deposited zinc oxide as a base material and provides a high transmission rate in the visible light range, a high conductivity, and a high adhesiveness to a resin substrate, and a manufacturing method thereof.

2. Description of the Related Art

As transparent electrodes for devices in display devices such as liquid crystal and plasma displays, thin-film solar batteries, input devices such as touch panels, and electronic devices such as light-emitting diodes, indium tin oxide (ITO), fluorin-doped tin oxide (SnO₂: F), boron-, aluminum- or gallium-doped zinc oxide (ZnO) films, etc. are used. The zinc oxide film doped by any one of atom selected from boron, aluminum, gallium etc. which provides conductivity will be called as the doped zinc oxide film or the conductive zinc oxide film hereafter.

Of those electrodes, ITO films are widely used for liquid crystal display devices because of its resistivity as low as 1 to 3×10⁻⁴ Ω·cm.

However, since ITO films turn black in oxygen plasma due to reduction, they cannot be used as electrodes in a process in which amorphous silicon is deposited by chemical vapor deposition, following a ZnO deposition process, as in the case of solar battery manufacturing process. Furthermore, indium (In), an element constituting the ITO film, is expensive and scarce rare metal.

On the other hand, fluorin-doped SnO₂:F films whose resistivity is as high as 10⁻³ Ω·cm are not suitable for films required to provide high conductivity.

Meanwhile, a doped ZnO film, which is generally manufactured by sputtering, has resistivity of approximately 4 to 6×10⁻⁴ Ω·cm, lower than that of the SnO₂ film. In addition, ZnO films are chemically stable compared with ITO films, which is why they are used as electrodes of solar batteries using an amorphous silicon film. Furthermore, zinc (Zn), an element constituting the ZnO film, is inexpensive and abundant resource.

To use doped ZnO films for liquid crystal display devices etc., their resistivity must remain at 4 to 6×10⁻⁴ Ω·cm or lower. To obtain this value, the film thickness must fall within 120 nm to 160 nm range.

To use the transparent ZnO conductive film as a common electrode on the side of a color filter layer, a high-adhesion deposition process, in which ZnO is deposited on a resin-coated base substrate, is required.

A manufacturing equipment adopting a DC magnetron sputtering process has been widely used. By using this equipment, the deposition of doped ZnO film even on a large-area substrate in 10th-generation mother glass size can be possible.

Japanese Patent Laid Open Application, JP H09 (1997)-291356 A (“JP '356” hereinafter) discloses the use of a doped ZnO film as a transparent electrode for a liquid crystal display device. This prior art discloses a structure of a transparent conductive film, in which a silver (Ag) film 3 sandwiched between the ZnO transparent conductive layers 2 is placed on a base substrate 1, and an ITO film is formed on a ZnO film that constitutes the uppermost layer (See JP '356, paragraphs [0017] to [0029] and FIGS. 1 to 3.). The use of the base substrate 1 which was formed by a color filter layer 7, an acrylic resin layer 8, and an inorganic interlay 9 on a glass substrate 10 is also disclosed (See JP '356, paragraph [0017].).

However, since the transparent electrode disclosed in the prior literature uses an Ag film 3, transmittance decreases. To minimize the reduction of transmittance, the Ag film 3 must be formed thin, but this control is unfeasible. In addition, a major element of the ITO film 11 used as the uppermost layer is indium (In), which is a rare metal and therefore expensive. Furthermore, this prior literature does not give any consideration to the fluctuation of sheet resistance of the ZnO film that occurs when the color filter layer is subjected to heat treatment.

The use of Ag and ITO, in addition to ZnO, in the transparent conductive film in the previous literature thus causes various problems.

### SUMMARY OF THE INVENTION

Accordingly, to solve these problems, the present invention is directed to a display substrate whose transparent electrode is a ZnO layer having reduced characteristics change against heat treatment, and a method of manufacturing such a display substrate.

As a result of conducting intensive research, the present inventors have found that in a transparent electrode consisting of a zinc oxide, by forming two or more layers having different resistivity values on a substrate including an organic resin layer such as color filter layer, a neatly-designed transparent conductive film providing a high transmission rate and a low resistance in the visible light range can be created. The finding has led to successful completion of the present invention.

To achieve object mentioned above, the present invention provides a display substrate comprising: a supporting substrate; an organic resin layer formed on the supporting substrate; and a transparent electrode formed on the organic resin layer, wherein the transparent electrode includes a first layer containing a zinc oxide and formed in close contact with the organic resin layer and a second layer containing a zinc oxide and which has a thickness thicker than a thickness of the first layer and is formed on the first layer. Here, the first layer is deposited by either one of a DC sputtering and a DC magnetron sputtering, and the second layer is deposited by any one of a radio frequency sputtering, a radio frequency magnetron sputtering, a radio frequency superimposing a DC sputtering, and a radio frequency superimposing a DC magnetron sputtering.

In another aspect, the present invention provides a second structure of a display substrate comprising: a supporting substrate; an organic resin layer formed on the supporting substrate; and a transparent electrode formed on the organic resin layer, wherein the transparent electrode including: a first layer containing a zinc oxide and formed in close contact with the organic resin layer; and a second layer containing a zinc oxide, which has a resistivity lower than a resistivity of the first layer, in which thickness is thicker than a thickness of the first layer, and is formed on the first layer.

In another aspect, the present invention provides a display device comprising: a TFT substrate including an organic resin layer and a first transparent conductive layer formed on the organic resin layer; a display substrate including a color filter layer formed of an organic resin and a second transparent conductive layer containing a zinc oxide and formed on the color filter layer; and a display element interposed between the TFT substrate and the display substrate, wherein at least one of the first transparent conductive layer and the second transparent conductive layer including: a first layer formed in close contact with the organic resin layer and the color filter layer; and a second layer is formed on the first layer and is thicker than the first layer.

In the above display device, the first layer is formed by either one of a DC sputtering and a DC magnetron sputtering, the second layer is formed by any one of a radio frequency sputtering, a radio frequency magnetron sputtering, a radio frequency superimposing a DC sputtering, and a radio frequency superimposing a DC magnetron sputtering.

In another aspect, the present invention provides a display device comprising: a TFT substrate including an organic resin layer and a first transparent conductive layer formed on the organic resin layer; a display substrate including a color filter layer formed of an organic resin and a second transparent conductive layer containing a zinc oxide and in which thickness is thicker than a thickness of the first transparent conductive layer and is formed on the color filter layer; and a display element interposed between the TFT substrate and the display substrate.

In the above display device, each of the first transparent conductive layer and the second transparent conductive layer includes: a first layer containing a zinc oxide and formed in close contact with the organic resin layer and the color filter layer; and a second layer containing a zinc oxide, and which has a resistivity lower than a resistivity of the first layer, in which thickness is thicker than a thickness of the first layer, and is formed on the first layer.

Furthermore, in another aspect, the present invention provides a method of manufacturing a display substrate comprising: forming an organic resin layer on a supporting substrate; and forming a transparent electrode on the organic resin layer, wherein forming the transparent electrode includes: forming a first layer containing a zinc oxide in close contact with the organic resin layer by either one of a DC sputtering and a DC magnetron sputtering; and depositing a second layer containing a zinc oxide on the first layer by one of a radio frequency sputtering, a radio frequency magnetron sputtering, a radio frequency superimposing a DC sputtering, and a radio frequency superimposing a DC magnetron sputtering.

It is to be understood that the present invention provides a display substrate comprising a transparent conductive film, which provides a high adhesion to a resin-coated substrate, a high transmission rate in the visible light range, a low resistance, and neat appearance thanks to its simple structure, a manufacturing method thereof, and a display device adopting the display substrate. The present invention is applicable not only to color filters but also to transparent ZnO electrodes on other resin substrates.

### BRIEF DESCRIPTION OF DRAWINGS

In the drawings:

FIG. 1 illustrates a cross-sectional structure according to an embodiment of the present invention;

FIG. 2 is a cross-sectional view of a typical modification of the display substrate;

FIG. 3 is a cross-sectional view of another modification of the display substrate;

FIGS. 4A and 4B are the charts illustrating the thermal desorption characteristics of a gallium-doped zinc oxide (GZO) film deposited on a glass substrate, in which FIG. 4A shows a deposition performed by a DC magnetron sputtering, and FIG. 4B shows a deposition performed by a radio frequency superimposing a DC magnetron sputtering;

FIGS. 5A and 5B are the charts illustrating the relation between the residual compressive stress of a GZO film deposited on a glass substrate and the substrate temperature, in which FIG. 5A illustrates the case that the GZO film is deposited by a DC magnetron sputtering, and FIG. 5B illustrates the case that the GZO film is deposited by a radio frequency superimposing a DC magnetron sputtering;

FIG. 6 illustrates schematically a partial cross sectional view of a display part of a display device according to the present invention;

FIG. 7 is a flow chart illustrating a typical manufacturing method of a liquid crystal display device using a display substrate;

FIGS. 8A and 8B are the images of the surface of a display substrate under an atomic force microscope (AFM), in which FIG. 8A shows Comparative Example 2, and FIG. 8B shows Example 2;

FIGS. 9A and 9B are the images of the cross section of the display substrate in Example 1 under a transmission electron microscope (TEM), in which FIG. 9A shows a low-magnification image, and FIG. 9B shows a high-magnification image;

FIGS. 10A to 10C are the images of the cross section of the display substrate in a Comparative Example 2 under a TEM, in which FIG. 10A shows a low-magnification image, and FIGS. 10B and 10C show high-magnification images;

FIGS. 11A and 11B are the electron diffraction images of a display substrate, in which FIG. 11A shows the image of Example 1, and FIG. 11B shows the image of Comparative Example 1;

FIG. 12 is a chart illustrating the results of X-ray diffraction measurement of the display substrate in Example 1 and Comparative Example 2;

FIG. 13 is a chart illustrating the ratio of surface diffraction intensity (101) of Examples 1 to 3 and Comparative Examples 2, 3, and 5 to that of reference surface diffraction intensity (100) ((101)/(100)); and

FIGS. 14A to 14C are the charts illustrating the results of elemental analyses in the direction of depth from the surface by Auger electron spectroscopy of the display substrate in Example 1, Comparative Example 2, and Example 3, in which FIG. 14A shows the results of Example 1, FIG. 14B shows those of Comparative Example 2, and FIG. 14C shows those of Example 3.

### DETAILED DESCRIPTION OF THE PREFERRED EMBODIMENTS

Hereinafter, embodiments of the present invention will be described in detail with reference to the figures in which like reference characters are used to designate like or corresponding components.

### (Display Substrate)

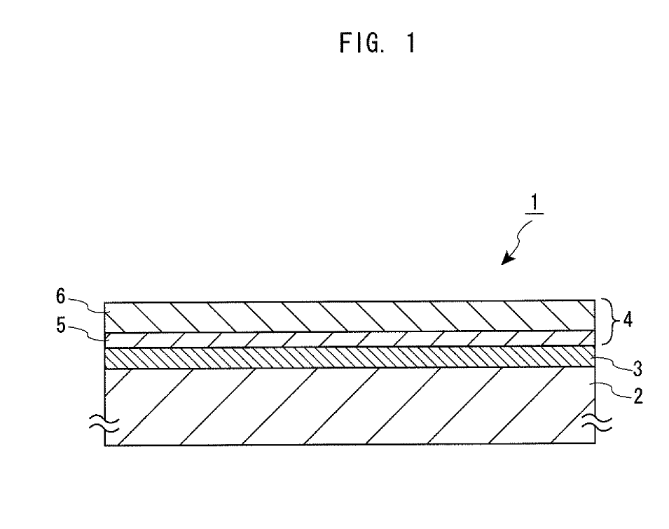

FIG. 1 illustrates a cross-sectional structure according to an embodiment of the present invention.

The display substrate 1 includes a supporting substrate 2, an organic resin layer 3 formed on the supporting substrate 2, and a transparent doped ZnO electrode 4 formed on the organic resin layer 3. The transparent electrode 4 includes a first layer 5 formed on the organic resin layer 3 in adhered contact with the organic resin layer 3, and a second layer 6 deposited on the first layer 5. As details will be described later, an alignment layer is printed on a transparent electrode 4, and the printed layer is sintered by heat treatment. A resistivity (i.e. specific resistance) of the transparent electrode 4 after heat treatment is set to fall within the 3 to 7 μΩ·m range. A resistivity of the second layer 6 of the transparent electrode 4 is set to be lower than that of the first layer 5. It is desirable that the resistivity of the second layer 6 be less than 7 μΩ·m. The resistivity of the first layer 5 may be 7 μΩ·m or higher.

A glass or resin substrate can be used for the supporting substrate 2.

To obtain the above resistivity value, gallium (Ga) or aluminum (Al) is added to ZnO of the first layer 5 and the second layer 6.

The first layer 5 can be formed by a DC sputtering or a DC magnetron sputtering. Furthermore, to maintain the resistivity of the second layer 6 at a lower level than that of the first layer 5, the second layer 6 can be formed by one of the following methods such as a radio frequency sputtering, a radio frequency magnetron sputtering, a radio frequency superimposing a DC sputtering, and a radio frequency superimposing a DC magnetron sputtering.

An organic resin layer 3 is comprised of red (R), green (G), and blue (B) color filters with pigments of these colors added to a transparent organic resin such as acrylic resin. Such the display substrate 1 can be used for a liquid crystal display device.

It is desirable that the film thickness of the first layer 5 falls within the 10 to 50 nm range, whereas that of the second layer 6 falls within the 60 to 200 nm range. This film thickness composition ratio can be reversed. It is preferable that the total film thickness of the first layer 5 formed on the color filter layer 3 and the second layer 6 formed on the first layer 5 falls within the 100 to 200 nm range.

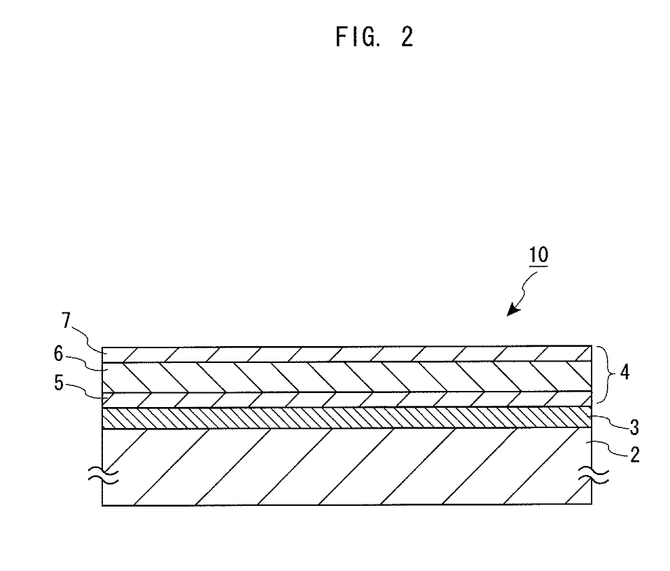

FIG. 2 is a cross-sectional view of a typical modification of the display substrate 1.

A display substrate 10 differs from the display substrate 1 in FIG. 1 that the former includes a doped ZnO third layer 7 formed on the second layer 6 of the transparent electrode 4, and that a resistivity of the third layer 7 is set to be higher than that of the second layer 6. The resistivity of the third layer 7 may be set to 7 μΩ·m or higher as in the case of the first layer 5.

The third layer 7 can be formed as same as the first layer 5 by ZnO sputtering that Ga or Al is doped by a DC sputtering or a DC magnetron sputtering.

In the display substrate 10 which has a three-layered structure, it is preferable that the film thickness of the first layer 5 falls within the 20 to 30 nm range, that of the second layer 6 falls within the 60 to 140 nm range, and that of the third layer 7 falls within the 20 to 30 nm range. It is also desirable that the total film thickness of the first layer 5, the second layer 6, and the third layer 7 falls within the 100 to 200 nm range.

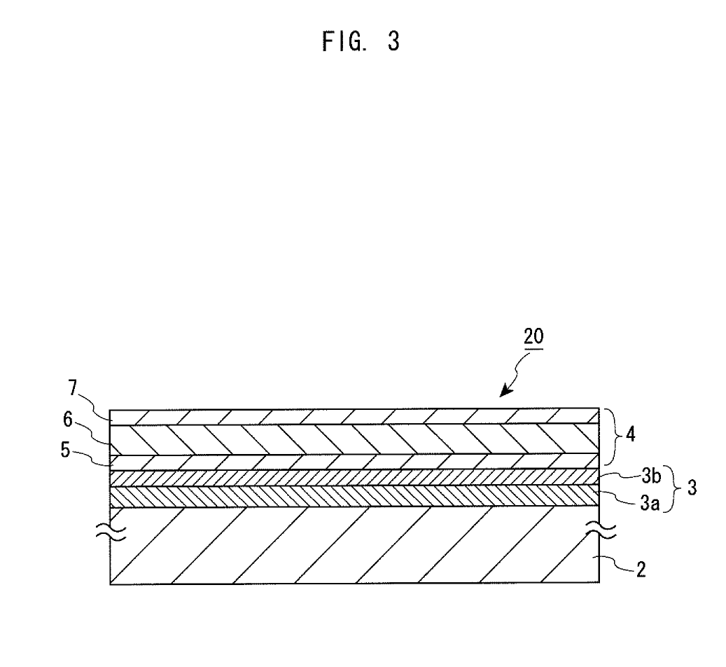

FIG. 3 is a cross-sectional view of another display substrate 20, modification from the display substrate 10.

The display substrate 20 differs from the display substrate 10 in that the organic resin layer 3 of the display substrate 20 includes a color filter layer 3a and a buffer layer 3b. The buffer layer 3b is formed preferably by the spin coat method on the color filter layer 3a to make the upper face of the color filter layer 3a flat. A transparent epoxy resin or acrylic resin, for example, can be used for the buffer layer 3b. The buffer layer 3b also improves the resistance to heat and chemicals treatments.

### (Method of Manufacturing Display Substrates)

The transparent electrode 4 consisting of a zinc oxide (ZnO) to be deposited on the display substrate can be formed by sputtering using a ZnO target that aluminum (Al) or gallium (Ga) is added specifically. Al and Ga can be added to the transparent electrode 4 made of a zinc oxide.

In this case, Al doped zinc oxide (ZnO) is called as aluminum zinc oxide (AZO), Ga doped ZnO is called as gallium zinc oxide (GZO), and both Al and Ga doped ZnO is called as aluminum gallium zinc oxide (AGZO).

When the transparent electrode 4 is to be deposited by sputtering, it is desirable to use ZnO as the target in which aluminum oxide or gallium is contained in 3 to 15% by weight of the total weight of aluminum oxide or gallium, and ZnO.

The first layer 5 of the transparent electrode 4 consisting of a zinc oxide can be formed by the DC sputtering or the DC magnetron sputtering. Furthermore, the second layer 6 of the transparent electrode 4 made of a zinc oxide can be formed by one of the radio frequency sputtering, the radio frequency magnetron sputtering, the radio frequency superimposing the DC sputtering, and the radio frequency superimposing the DC magnetron sputtering processes, to allow the resistivity of the second layer 6 of the transparent ZnO electrode 4 to remain lower than that of the first layer 5.

If the transparent electrode 4 is formed on the supporting electrode 2 covered with the organic resin layer 3 by the DC sputtering or the DC magnetron sputtering, the sheet resistance of the film deposited in thickness of approximately 150 nm is as high as 74.3Ω/□ for example. However, the damage to the organic resin layer 3 was small.

Meanwhile, the sheet resistance of the film deposited in thickness of 150 nm by any one of the radio frequency sputtering, the radio frequency magnetron sputtering, the radio frequency superimposing DC sputtering, and the radio frequency superimposing the DC magnetron sputtering processes is as low as 38.2Ω/□ for example. However, the damage to the organic resin layer 3 was large.

It is described below that the reason why the ZnO first layer formed on an organic resin layer 3 by the DC sputtering or the DC magnetron sputtering causes less damage to the organic resin layer 3 such as a color filter layer etc. and provides high resistance to heat.

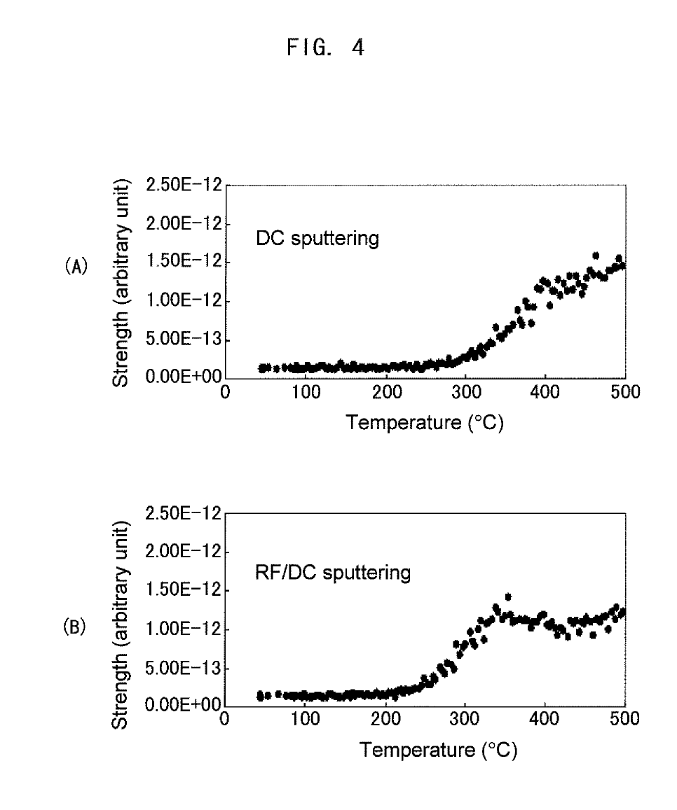

FIGS. 4A and 4B are the charts illustrating the thermal desorption characteristics of a gallium-doped zinc oxide (GZO) film deposited on a glass substrate. FIG. 4A demonstrates the results obtained from a film deposited by a DC magnetron sputtering and FIG. 4B shows the results obtained from the film deposited by a radio frequency superimposing a DC magnetron sputtering. In the characteristics of TDS (Thermal Desorption Specriscopy) of FIGS. 4A and 4B, temperature are plotted on the horizontal axis, and strengths are plotted on the vertical axis (arbitrary unit).

When the GZO film is deposited directly onto the glass substrate, there was a certain temperature that a stress starts to decrease sharply during a first temperature increase process. This temperature is approximately 250 to 300° C. when the DC magnetron sputtering is used, and that was 200 to 250° C. when the radio frequency superimposing the DC magnetron sputtering was used.

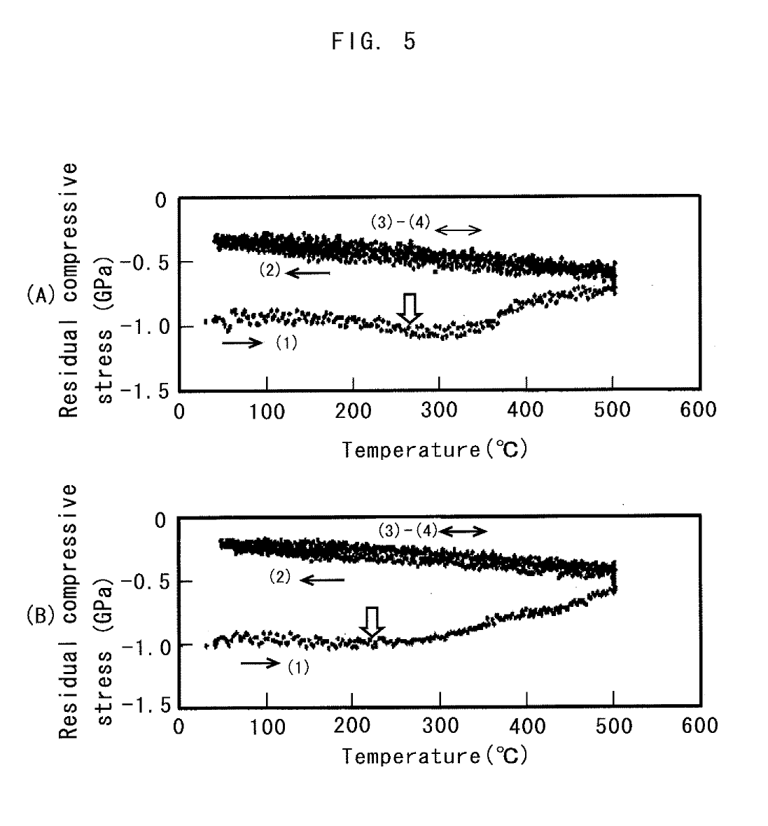

FIGS. 5A and 5B illustrate the relation between substrate temperature and the residual compressive stress of a GZO film. FIG. 5A illustrates the case in which the GZO film is deposited by a DC magnetron sputtering, and FIG. 5B illustrates the case in which the GZO film is deposited by a radio frequency superimposing a DC magnetron sputtering. The ordinate axis of the graph represents the residual compressive stress (GPa) and the abscissa axis of the graph represents the temperature (° C.) of the substrate.

The substrate temperature was changed as following steps shown below:

Cycle 1: Temperature was increased from room temperature to 500° C.

Cycle 2: After cycle 1, the temperature was then decreased from 500° C. to room temperature.

Cycle 3 to 4: After cycle 2 was completed, cycles 1 and 2 were repeated again.

In cycle 1, the compressive stress decreased with the increase of substrate temperature, and in cycle 2, the compressive stress decreased with the decrease of substrate temperature. In cycles 3 and 4, the compressive stress increased and then decreased, following the same graphic plot as cycle 2. An important point to note here is that in the case of deposition by the DC magnetron sputtering as shown in FIG. 5A, the residual compressive stress was found to start decreasing sharply when the substrate temperature was around 250 to 300° C. In the case of deposition by the radio frequency superimposing the DC magnetron sputtering as shown in FIG. 5B, the temperature at which residual compressive stress started decreasing sharply was around 200 to 250° C.

Then, it is obvious that the decrease of residual stressth is closely related to a sublimation of zinc. In addition, when zinc is sublimated, an increase of the resistance of the transparent electrode made of a zinc oxide will be estimated. Consequently, the ZnO film deposited by the DC magnetron sputtering process has a high heat resistance, although its resistivity is slightly higher than the film formed by the radio frequency superimposing the DC magnetron sputtering. It is considered that the same phenomenon has occurred when ZnO is deposited on the organic resin layer of the present invention.

According to the method of manufacturing a display substrate 1 of the first embodiment, the transparent electrode 4 having the low sheet resistance and causing minimum damage to the organic resin layer 3 can be formed by forming the first layer 5 of the transparent electrode 4 made of a zinc oxide thin on the supporting substrate 2 covered with the organic resin layer 3, and then depositing the second layer 6 thick to make the sheet resistance of the transparent electrode 4 to remain small.

When the transparent electrode 4 having two- or three-layered structure is formed by sputtering, it having a desired electrical and optical characteristics may be obtained by using the AZO or GZO target in the same type or same composition and by controlling conditions within a vacuum chamber. Especially, the deposited film may be obtained by switching the sputtering power supply for deposition from the DC to the radio frequency and back to the DC. In this case, it is desirable to control the amount of gas to be fed into the vacuum chamber such as oxygen, thus maintaining the oxygen content of the film in the optimum range.

In the process using the DC sputtering or the DC magnetron sputtering, the horizontal component of the incidence angle of particles to the supporting substrate 2 may be controlled to become larger than that of the vertical one.

The supporting substrate 2 and the target used for each sputtering process may be placed relatively concentrically, and the deposition may be performed while the supporting substrate 2 is being rotated.

The face of the supporting substrate 2 and that of the target to be used in each sputtering process may be placed parallel to each other, and the deposition may be performed while the face of the supporting substrate 2 is transferred several times along the front face of the target.

Any one from argon (Ar), krypton (Kr), and xenon (Xe) gases can be used for sputtering.

### (Display Device)

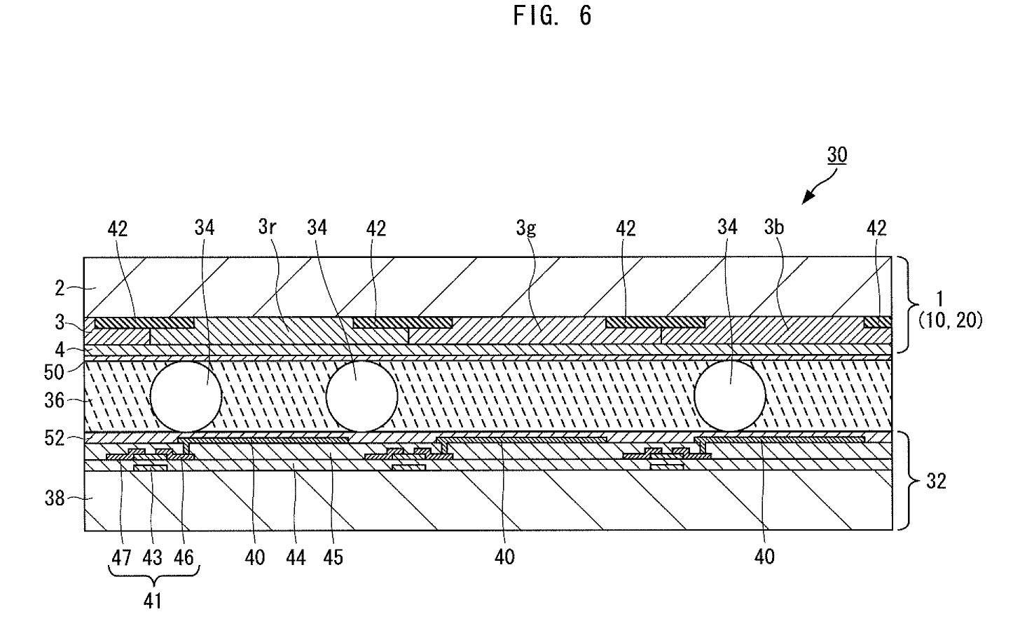

FIG. 6 illustrates schematically a partial cross sectional view of a display part of a display device according to the present invention.

A display part 30 as shown in FIG. 6 is a typical liquid crystal display device. The display part 30 includes a display substrate 1 which serves as a base substrate having a color filter layer, a TFT substrate 32, and a liquid crystal 36 to be interposed between the display substrate 1 and the TFT substrate 32 via a spacer 34. The display substrate 1 of the color filter layer may be substituted by display substrate 10 or 20, which is a modification example from the display substrate 1.

The TFT substrate 32 is the substrate on which a TFT 41 is formed to be connected to each pixel electrode 40 formed on a glass substrate 38. As shown in FIG. 6, each pixel has three TFT's 41 for red, green, and blue color display. The red, green, and blue color filter layers 3r, 3g, and 3b are disposed on the pixel electrode 40 and a black mask 42 is disposed at the boundaries of the color filter layers 3r, 3g, and 3b. The depicted TFT 41 is provided with an embedded gate electrode 43 which serves as a control electrode, a first insulating layer 44 which serves as a gate insulating film, and a second insulating layer 45 formed on the first insulating layer 44. A drain electrode 46 of the TFT 41 is connected to the pixel electrode 40 through a window portion of the second insulating layer 45. A data signal is applied to each source electrode 47 of the TFT 41.

In addition to the display part 30, the liquid crystal display device is constructed to be provided with a scanning signal line driving circuit for scanning the signal lines of the display part 30 to which the images are displayed according to image data, a data signal line driving circuit for supplying display signal voltage to the data signal lines of the display part 30 based on image data, a common voltage generation circuit for applying a specified voltage to the common electrode of the display part 30, and a control part for synchronizing each driving part by outputting various control signals. Furthermore, the liquid crystal display device may include an image memory for temporarily storing image data input from outside.

The case that the display device is made by the liquid crystal element inserted between the TFT substrate 32 and the display substrate 1 has been described. The display device may be made of another device such as an organic EL, for example.

### (Method of Manufacturing a Display Device)

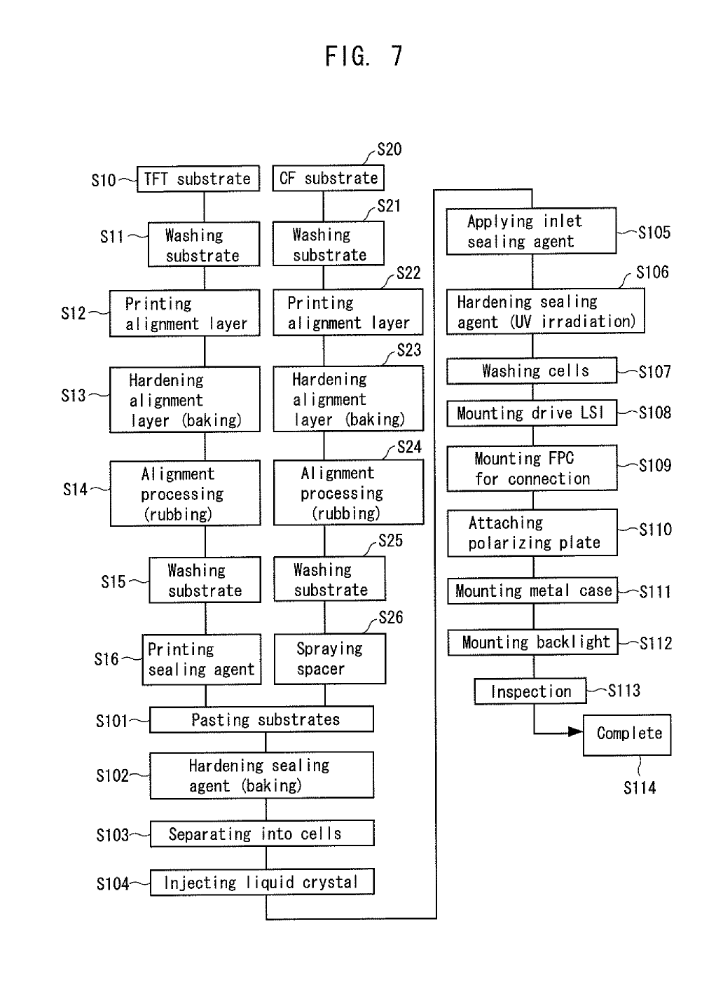

FIG. 7 is a flow chart illustrating a typical example of manufacturing method of a liquid crystal display device using a display substrate 1, 10, or 20.

As shown in FIG. 7, when the display part 30 having color filters R, G, and B is fabricated to be formed within the display substrate 1, 10, or 20 placed opposite to a TFT substrate 32 (See FIG. 6.), at first, a color filter (CF) substrate, which is provided with the organic resin layer 3 having the black mask 42, color filter layers 3r, 3g, and 3b and the transparent electrode 4 is prepared at first on the side of the display substrate (step S10).

Meanwhile, a TFT substrate, which is provided with the TFT 41, the first insulating layer 44, and the second insulating layer 45 onto the glass substrate 38 is also prepared on the side of the TFT substrate (step 20).

The substrates for TFT and CF are then washed (steps S11 and S21) and dried. An alignment layer is printed (steps S12 and S22) and then hardened by sintering with using an infrared ray (steps S13 and S23). This heat treatment is performed at a temperature of 180 to 250° C. for 30 to 60 minutes. The hardened alignment layer is then subjected to alignment process by rubbing and other methods (steps S14 and S24).

Each substrate is then washed (steps S15 and S25), a sealing agent (not shown) is applied to the CF substrate (step S16), and the spacer 34 is attached over the entire surface by spraying (step S26). In this case, the sealing agent may be applied to the CF substrate, and the spacer 34 may be formed on the TFT substrate 32. In addition, both the sealing agent and the spacer 34 may be formed onto one of the substrates.

The substrates for TFT 32 and CF 1 are then aligned to be positioned and to be pasted each other via the sealing agent by thermo compression bonding (step S101), and the sealing agent is hardened (step S102).

The pasted substrates are then separated into an individual cell (step S103), and the liquid crystal is injected from an inlet (step S104).

The inlet is then sealed with an ultraviolet-curing type adhesive agent (step S101). This adhesive agent is hardened by irradiation of the ultraviolet irradiation (step 106).

The cells are washed (step S107) as required, and a drive LSI is mounted (step S108).

Next, a flexible printed circuit board (FPC) connected to the drive circuit board is mounted (step S109), a polarizing plate is attached to the bottom face of the TFT substrate and the top face of the CF substrate (step S110), the assembly is encapsulated in a metal case (step S111), and a backlight is mounted (step S112).

The display part thus manufactured is then inspected (step 113) and it is completed by passing the testing items (step S114).

The liquid crystal display device having color filters on the TFT substrate 32 can also be fabricated. In this case, the CF substrate 1, in which black mask 42 and the transparent electrode 4 are formed on the supporting substrate 2 (not shown), may be prepared.

Moreover, the TFT substrate 32 may be prepared by the following processes that the insulating layer 44 and the second insulating layer 45 are formed onto the glass substrate 38 as shown in FIG. 6, and then the organic resin layer 3 including color filter layers 3r, 3g, and 3b is formed on the second insulating layer 45.

The region that serves as a connection between the drain electrode 46 and the pixel electrode 40 of the organic resin layer 3 is opened through photolithography and etching processes.

A transparent electrode is formed by deposition, and the deposited transparent electrode undergoes a resist coating, an exposure, an etching, and a resist washing removal processes for microfabrication to form a pixel electrode 40. The subsequent processes are the same as those shown in FIG. 7.

### Example 1

Hereinafter, an example of the present invention will be described in more detail.

A commercially available substrate having color filter layers (organic resin layer) 3 is prepared. The transparent electrode film 4 made of GZO was deposited by sputtering onto the color filter layer 3. The used supporting substrate 2 was the glass substrate containing no alkaline. For an example, this supporting substrate is #1737 made by the Corning Incorporated. A size of the glass supporting substrate 2 was 320 mm×440 mm. The sputtering equipment changeable between the DC sputtering mode and the DC/RF sputtering mode, in which DC radio frequency power is superimposed upon the DC sputtering, was used. The ratio of DC power to RF power was set to 1:1 in the DC/RF mode, and the frequency of RF power was set to 13.56 MHz.

The display substrate 1 in Example 1 was manufactured by depositing a GZO film, which serves as the first layer 5, onto the color filter layers 3 formed on the supporting substrate 2 in thickness of 30 nm in the DC sputtering mode, and then a GZO film, which serves as a second layer 6, in thickness of 130 nm in the DC/RF sputtering mode. The supporting substrate 2 was heated to 150° C.

### Example 2

The display substrate 10 in Example 2 was manufactured by depositing GZO film, which serves as the first layer 5, onto the color filter layer 3 formed on the same glass supporting substrate 2 as Example 1 in thickness of 20 nm in the DC sputtering mode. The GZO film was then deposited as the second layer 6 in thickness of 110 nm in the DC/RF sputtering mode, and then the GZO film as the third layer 7 in thickness of 20 nm in the DC sputtering mode. The conditions other than this deposition condition were the same manner as that of Example 1.

### Example 3

The display substrate 10 in Example 3 was manufactured by depositing the buffer layer 3b first in thickness of 20 nm onto the color filter layer 3a formed onto the same glass supporting substrate 2 in Example 1, the GZO film was then deposited as the first layer 5 in the DC sputtering mode in thickness of 20 nm, the GZO film as the second layer 6 in the DC/RF sputtering mode in thickness of 110 nm, and lastly the GZO film as the third layer 7 in the DC sputtering mode in thickness of 20 nm.

### Comparative Example 1

The display substrate in Comparative Example 1 was manufactured by depositing the GZO film onto the color filter layer 3a formed on the same glass supporting substrate 2 as Example 1 having the thickness of 150 nm in the DC sputtering mode. The conditions other than this deposition condition were the same manner as that of Example 1.

### Comparative Example 2

The display substrate in Comparative Example 2 was manufactured by depositing the GZO film on the color filter layer 3a formed on the same glass supporting substrate 2 as Example 1 having the thickness of 150 nm in the DC/RF sputtering mode. The conditions other than this deposition condition were the same manner as that of Example 1.

### Comparative Example 3

The display substrate in Comparative Example 3 was manufactured by depositing the GZO film as the first layer 5 on the color filter layer 3a formed on the same glass supporting substrate 2 as Example 1 having the thickness of 120 nm in the DC/RF sputtering mode. The GZO film as the second layer 6 was then deposited in thickness of 20 nm in the DC sputtering mode. The conditions other than this deposition condition were the same manner as that of Example 1.

### Comparative Example 4

The display substrate in Comparative Example 4 was manufactured by depositing the buffer layer 3b on the color filter layer 3a formed on the same glass supporting substrate 2 as Example 1 in thickness of 20 nm. The GZO film was then deposited in thickness of 150 nm in the DC/RF sputtering mode. The conditions other than this deposition condition were the same manner as that of Example as Example 1.

### Reference Example

The display substrate in Reference Example was manufactured by depositing an ITO film on the color filter layer 3 formed on the same glass supporting substrate 2 as Example 1 in thickness of 150 nm in the DC sputtering mode. The conditions other than this deposition condition were the same as manner as that of Example 1.

As shown in Table 1, the sheet resistance of a GZO film deposited on the color filter layer 3 along with deposition conditions. The sheet resistance (Ω/□) was measured by the 4-terminal method.

As shown in Table 1, the sheet resistance of the GZO film formed in Examples 1 to 3 was 33.8Ω/□, 32.7Ω/□, and 45.0Ω/□, respectively.

Meanwhile, the sheet resistance of the GZO film formed in Comparative Example 1 was as high as 74.3Ω/□. It is obvious that sheet resistance increases if the sputtering is performed only in the DC sputtering mode.

The sheet resistance of the GZO film formed in Comparative Example 2 was 36.4Ω/□. It is obvious that the sheet resistance is lower than that of Comparative Example 1 if the sputtering is performed only in the DC/RF sputtering mode.

The sheet resistance of the GZO film formed in Comparative Example 3 was 38.2Ω/□, slightly higher than that of Comparative Example 2.

In Comparative Example 4, the GZO film was formed in the DC/RF sputtering mode in the same thickness as Comparative Example 2 (160 nm), with the buffer layer 3b formed on the color filter layer 3. The sheet resistance of the GZO film in this case was 47.1Ω/□. This value is higher than that of Comparative Example 2.

The sheet resistance of the ITO film in Reference Example was 11.1Ω/□.

The sheet resistance of the GZO film in Examples 1 to 3 was found to be approximately the same as that of the GZO film deposited in the DC/RF sputtering mode in Comparative Example 2.

TABLE 1

| | Buffer | | | | | | | | Sheet | | |
|---|---|---|---|---|---|---|---|---|---|---|---|
| | layer | 1st layer | | 2nd layer | | 3rd layer | | Sheet | resistance | Rate of | |
| | Thick- | Depo- | Thick- | Depo- | Thick- | Depo- | Thick- | resis- | after heat | change of | Damage |
| | ness | sition | ness | sition | ness | sition | ness | tance | treatment | resistance | to color |
| | (nm) | method | (nm) | method | (nm) | method | (nm) | (Ω/□) | (Ω/□) | (%) | filter layer |
| Example 1 | None | DC | 20 | RF + | 130 | None | | 33.8 | 60.5 | 79 | Improved |
| | | | | DC | | | | | | | |
| Example 2 | None | DC | 20 | RF + | 110 | DC | 20 | 32.7 | 52.2 | 60 | Improved |
| | | | | DC | | | | | | | |
| Example 3 | 20 | DC | 20 | RF + | 110 | DC | 20 | 45 | 93.1 | 107 | No |
| | | | | DC | | | | | | | problem |

| Com. Ex. 1 | None | DC | 150 | None | | None | 74.3 | 86.2 | 16 | Small |
|---|---|---|---|---|---|---|---|---|---|---|
| Com. Ex. 2 | None | RF + DC | 150 | None | | None | 36.4 | 70.6 | 95 | Large |
| Com. Ex. 3 | None | RF + DC | 120 | DC | 20 | None | 38.2 | 65.3 | 71 | Large |

| | | | | | | | | | |
|---|---|---|---|---|---|---|---|---|---|
| Com. Ex. 4 | 20 | RF + DC | 150 | None | None | 47.1 | 102.2 | 117 | No |
| | | | | | | | | | problem |
| Ref. Ex | None | ITO | 150 | None | None | 11.1 | — | — | — |

The display substrates in Examples 1 to 3 and Comparative Examples 1 to 4 were subjected to heat treatment, and then the sheet resistance of each substrate was measured. The heat treatment was performed in the atmosphere at 230° C. for 30 minutes. This is the general heating condition for the hardening process of the alignment layer in step S23 of the flow chart as shown in FIG. 7. Table 1 lists the sheet resistances of the GZO film in Examples 1 to 3 and Comparative Examples 1 to 4 before and after the heat treatment, the rate of change (increase) of the sheet resistances between before and after the heat treatment, and the status of damages to the color filter layer 3.

The rate of change of resistance was found by using the equation (1) as shown below.

Rate of change of resistance=(Rs−R₀)/R₀×100(%) (1)

where R₀ is the sheet resistance measured before the heat treatment, and Rs is that measured after the heat treatment.

As shown in Table 1, the sheet resistances after the heat treatment and the rate of change of resistance in Examples 1 to 3 were generally found to be smaller than those of Comparative Examples. In addition, the damages to the color filter layer 3 in Examples 1 and 2 were found to have been improved. In Example 3, in which the buffer layer 3b was inserted, no damage was found.

In Table 1, the resistivities converted from the measured sheet resistances of the pixel electrode 40 before heat treatment in Examples 1 to 3 were 2.25 μΩ·m, 2.18 μΩ·m, and 3.00 μΩ·m, respectively. Thus, it was confirmed that the resistivity of the pixel electrode 40 before heat treatment was lower than 4.00 μΩ·m even if the fluctuation is taken into consideration. Meanwhile, the resistivities converted from the measured sheet resistances of the pixel electrode 40 after heat treatment were 4.03 μΩ·m, 3.48 μΩ·m, and 6.20 μΩ·mm, respectively.

These results indicate that the sheet resistance after heat treatment fell within the 3.00 μΩ·m to 7.00 μΩ·m range. It is therefore desirable that the sheet resistance fell within the 3.00 μΩ·m to 5.00 μΩ·m range. From above mentioned result, the first layer 5 only was deposited on the organic resin layer 3, and its resistivity was measured. The resistivity of the first layer 5 only was found to fall within the 7.00 μΩ·m to 9.00 μΩ·m range. It is therefore obvious that the resistivity of the second layer 6 itself is lower than 7.00 μΩ·m.

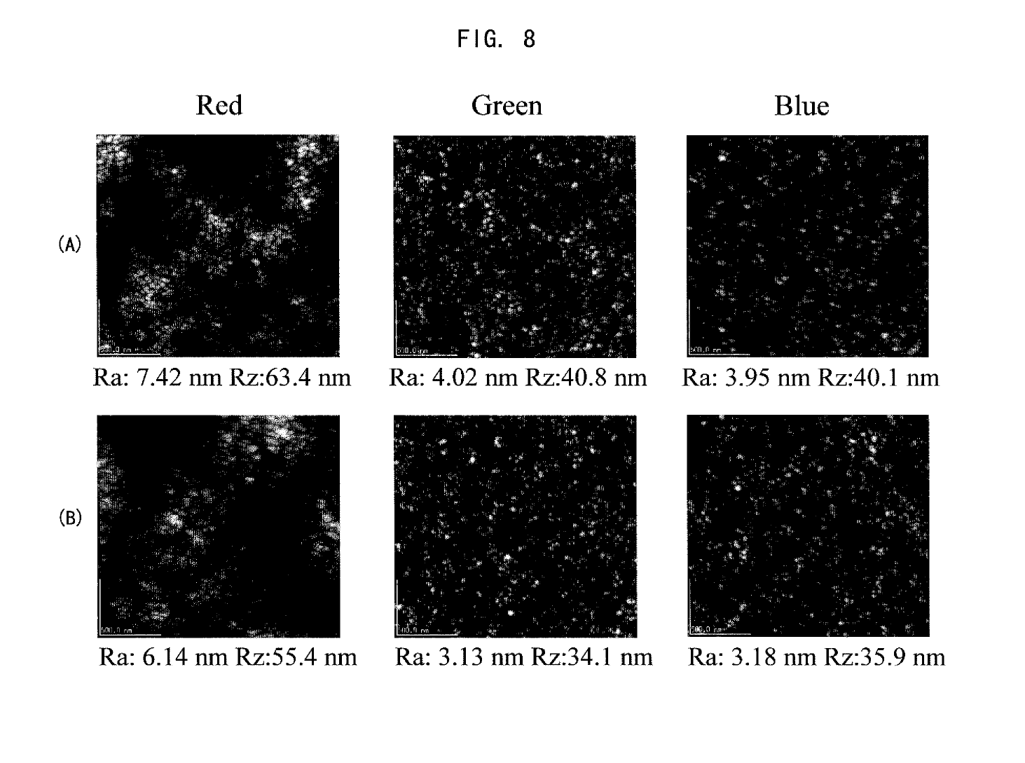

FIGS. 8A and 8B are images of the surface of a display substrate under an atomic force microscope (AFM), in which FIG. 8A shows Comparative Example 2, and FIG. 8B shows Example 2. Each image shows the measurement result obtained on the red, green, and blue filter respectively along with the surface roughness Ra (nm) and surface waviness Rz (nm) observed by the AFM. Surface roughness Ra is small unevenness in a local area as small as several nm. The surface waviness Rz (nm) is unevenness in an area of several tens of nm.

As shown in the images in FIG. 8, the degree of surface roughness Ra in Example 2 is lower than that of Comparative Example 2 on all of the red, green, and blue filters. Thus, it was confirmed that higher surface flatness has been achieved.

Table 2 summarizes the results of measurement of surface roughness of the display substrates in Examples 2 and 3 and Comparative Example 2.

As shown in Table 2, the degree of surface roughness Ra of Example 2 is lower than that in Comparative Example 2, meaning that the higher surface flatness has been achieved. It is obvious that the surface flatness on the red filter in Example 3 was especially improved in comparison with Comparative Example 2.

TABLE 2

| | Red | | Green | | Blue | |
|---|---|---|---|---|---|---|
| | Ra (nm) | Rz (nm) | Ra (nm) | Rz (nm) | Ra (nm) | Rz (nm) |
| Example 2 | 6.14 | 55.4 | 3.13 | 34.1 | 3.18 | 35.9 |
| Example 3 | 5.14 | 49.1 | 4.61 | 48.6 | 4.15 | 41.8 |
| Com. Ex. 2 | 7.42 | 63.4 | 4.02 | 40.8 | 3.95 | 40.1 |

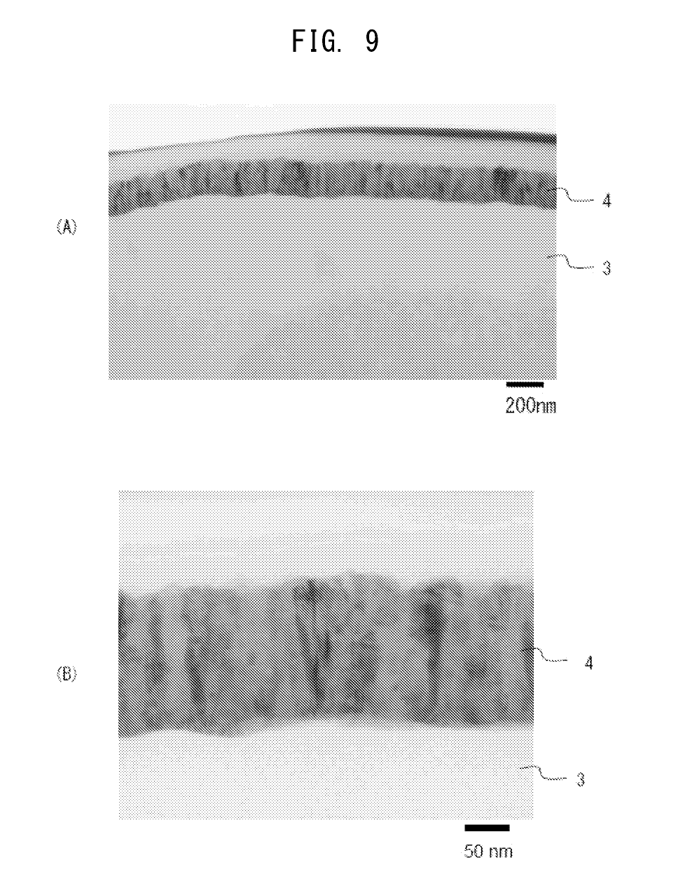

FIGS. 9A and 9B are the images of the cross section of the display substrate in Example 1 under a transmission electron microscope (TEM). FIG. 9A is a low-magnification image, and FIG. 9B is a high-magnification image.

As obvious in FIGS. 9A and 9B, a transparent columnar electrode 4 has been formed along the irregularities of the color filter layer 3 of the display substrate 1 in Example 1 and it means that c-axis orientation is high.

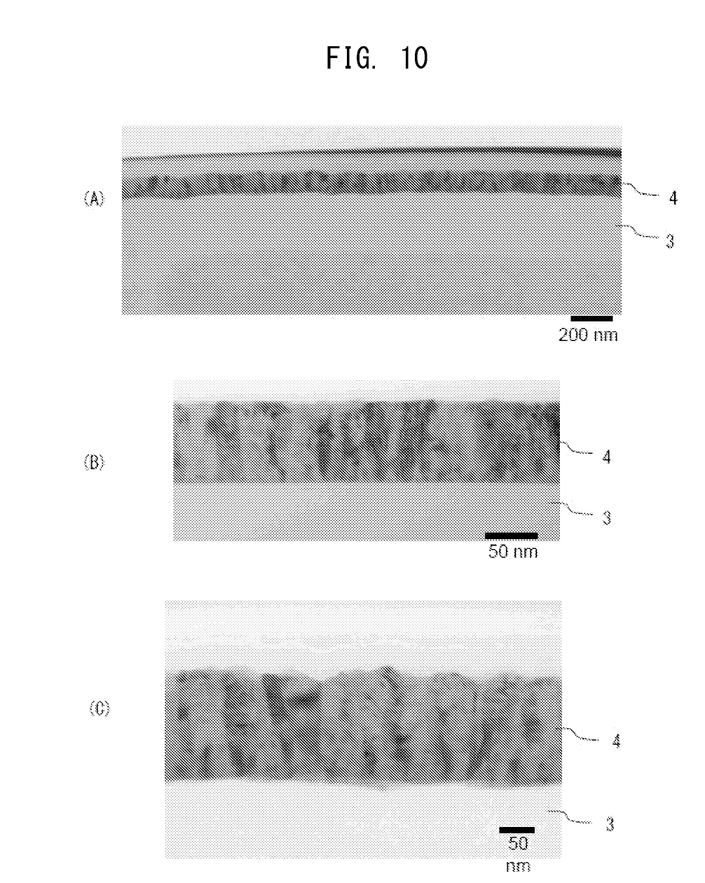

FIGS. 10A to 10C are the images of the cross section of the display substrate in Comparative Example 2 under a TEM. FIG. 10A is a low-magnification image, and FIGS. 10B and 10C are high-magnification images.

As shown in FIGS. 10A to 10C, a transparent columnar electrode 4 has been formed along the irregularities of the color filter layer 3 of the display substrate in Comparative Example 1. However, as shown in FIG. 10C, the orientation of the axis of the transparent columnar electrode 4 is not vertical in some portions. This indicates that the c-axis orientation is not as high as that in Example 1.

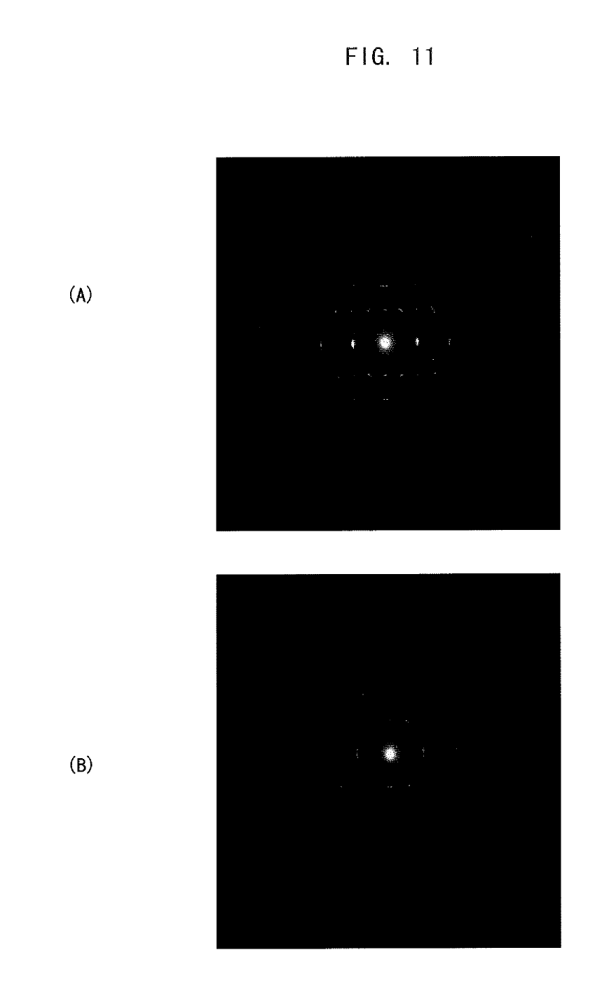

FIGS. 11A and 11B are electron diffraction images of a display substrate. FIG. 11A is the image of Example 1, and FIG. 11B is the image of the Comparative Example 1.

As shown in FIGS. 11A and 11B, the crystal quality in Example 1 is slightly better than that in Comparative Example 1.

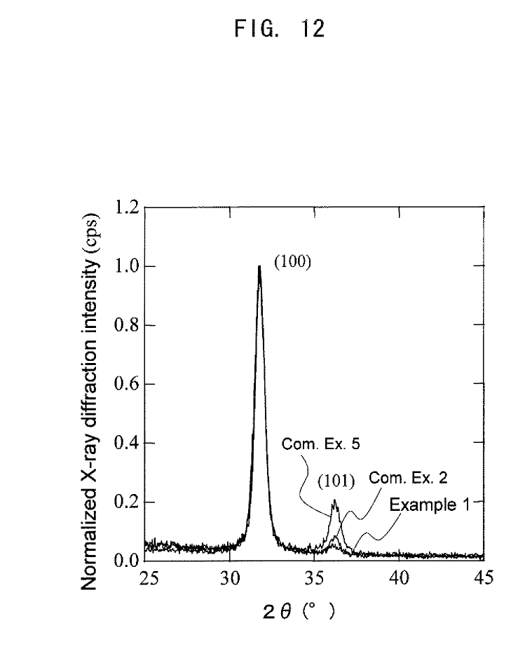

FIG. 12 is a chart illustrating the results of X-ray diffraction measurement of the display substrates in Example 1 and Comparative Example 2. In FIG. 12, the vertical axis indicates the X-ray diffraction intensity (arbitrary unit), namely the normalized values measured with respect to the (100) reference surface diffraction intensity, and the horizontal axis indicates the angle equivalent to the value twice as large as the angle of incidence θ of X-ray to the atomic plane. The measurement was performed on the same plane (i.e. in-plane measurement).

The (101) surface diffraction intensity in Example 1 was approximately 0.03 with respect to the (100) reference surface diffraction intensity. This indicates that the c-axis orientation in Example 1 is higher than that of Comparative Example 2.

In Comparative Example 5, in which the 20 nm-thick buffer layer 3b was formed on the color filter layer 3 and then the 150 nm-thick ZnO film was deposited by the DC/RF sputtering, the (101) surface diffraction intensity was approximately 0.2 with respect to the (100) surface diffraction intensity. This indicates that the degree of c-axis orientation is lower.

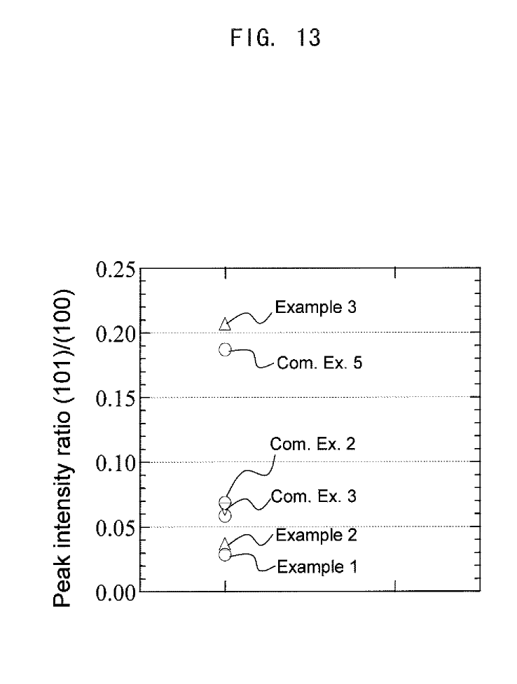

FIG. 13 is a chart illustrating the ratio of (101) surface diffraction intensity with respect to the (100) surface diffraction intensity ((101)/(100)) in Examples 1 to 3 and Comparative Examples 2, 3, and 5.

As shown in FIG. 13, the ratio of the (101) surface diffraction intensity with respect to the (100) surface diffraction intensity in Examples 1 and 2 was smaller than that in Comparative Examples 2 and 3. This indicates that the degree of c-axis orientation was higher in Examples 1 and 2. Especially, in Examples 1 and 2, which no buffer layer 3b were formed, the ratio of the (101) surface diffraction intensity with respect to the (100) surface diffraction intensity was lower than 0.05.

In Example 3, in which the 20 nm-thick buffer layer 3b was formed on the color filter layer 3, the ratio of the (101) surface diffraction intensity with respect to the (100) surface diffraction intensity was approximately 0.2 which was the same as in the case of Comparative Example 5 as shown in FIG. 11. This indicates that the degree of c-axis orientation in Example 3 was lower than that in Example 1.

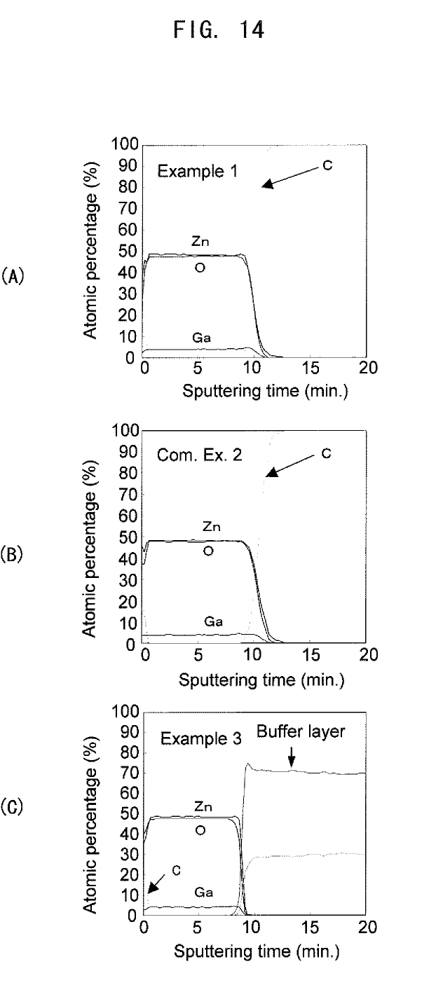

FIGS. 14A to 14C are charts illustrating the results of elemental analyses in the direction of depth from the surface by Auger electron spectroscopy of the display substrates in Example 1, Comparative Example 2, and Example 3. FIG. 14A shows the results of Example 1, FIG. 14B shows those of Comparative Example 2, and FIG. 14C shows those of Example 3. In FIGS. 14A to 14C, atomic percentage (%) is plotted on the vertical axis, whereas sputtering time (min.) is plotted on the horizontal axis.

In FIGS. 14A and 14B, carbon (C) at right side is a component of the color filter layer 3. It is obvious that the extension of the interface between the transparent electrode 4 consisting of Zn, 0, and Ga and the color filter layer 3 in Example 1 is slightly narrower than that of Comparative Example 2.

Meanwhile, as shown in FIG. 14C, it is obvious that the extension of the interface between the transparent electrode 4 consisting of Zn, O, and Ga and the buffer layer 3b was extremely narrow.

The above results indicate that in Examples 1 and 2, by providing the first layer 5 on a color filter layer 3, the c-axis orientation of the transparent electrode 4 increases. On the other hand, when the buffer layer 3b is formed on the color filter layer 3, the c-axis orientation decreases.

According to the Examples and Comparative Examples described above, the display substrates 1, 10, and 20 including the transparent conductive film in simple configuration can be obtained. The display substrates 1, 10, and 20 provide the high adhesiveness to the substrate with the organic resin layer 3, the high transmission rate in the visible light range, and the low resistance.

### Example 4

### Liquid Crystal Display Device

Display devices using display substrates 1, 10, and 20 in Examples 1 to 3 were manufactured. The display substrates 1, 10, and 20 in Examples 1 to 3 were used on the side of the counter electrode of the liquid crystal display device. A TFT substrate 32 having a diagonal size of 3 inches manufactured by the facility of present inventors was used. A transparent ITO electrode was used for the pixel electrode 40 of this TFT substrate 32.

As shown in the flow chart in FIG. 7, after inserting the spacer 34 between the display substrate 1 and the TFT substrate 32, the display substrate 1 and TFT substrate 32 were pasted together, and then the sealing agent was hardened. The substrates were then separated into individual cells. The liquid crystal 36 was injected into the 3 inches crystal cells thus separated. The 3 inches display part 30 was fabricated following the procedure as shown in the flow chart.

The display part 30 has the effective display area of 3 inches in diagonal size, 240×960 pixel matrix, and the total number of pixels is 230×400.

The assembled display part 30 was connected to a driving part to finish the liquid crystal display device of the present invention. Lighting check was then performed to make sure that all of the liquid crystal display devices using any one of the display substrates 1, 10, and 20 in Examples 1 to 3 were lit. No defects were found with the display part 30. In addition, the improper alignment of the liquid crystal 36 was not found, either, even when the transparent ZnO electrode 4 on the color filter layer 3 side and a transparent electrode on the pixel side having ITO electrodes were used. The associated abnormalities in characteristics were not found.

According to Example 4, the lighting of the 3 inches liquid crystal display device, in which the display substrate 1, 10, or 20 including the transparent ZnO electrode 4 was used as a counter electrode and a transparent ITO electrode was used as the TFT substrate 32, was realized. It is worth noting here that at least one of the display substrates, 1, 10, and 20 was replaced by the transparent electrode 4 made of a zinc oxide as compared to the conventional liquid crystal display device having transparent ITO electrodes for both the TFT substrate 32 and the counter substrate.

Each Example of the present invention was described assuming that the transparent electrode 4 formed on the supporting substrate 2 having color filters 3a only was made of a zinc oxide. However, the present invention allows the pixel electrode 40 formed on the TFT substrate 32 to be made of a zinc oxide having the same layer structure as the transparent electrode 4 described above.

In addition, the present invention is also applicable to the transparent electrode for driving display element such as organic EL element, in addition to liquid crystal display element. To apply the present invention to an organic EL display device, at first, a glass substrate 38 as shown in FIG. 6 is prepared that a TFT 41, a first insulating layer 44, and a second insulating layer 45 are formed onto the glass substrate 38. Then form a ZnO anode having the same layer structure as the transparent electrode 4 on the second insulating layer 45, deposit an organic EL light-emitting element on the anode, and form a cathode connected to a corresponding TFT 41 on the organic EL element.

Additional advantages and modifications will readily occur to those skilled in the art. Therefore, the invention in its broader aspects is not limited to the specific details and representative Examples shown and described herein. Accordingly, various modifications may be made without departing from the spirit or scope of the general inventive concept as defined by the appended claims and their equivalents.

What is claimed is:

1. A display substrate comprising:
a supporting substrate;
an organic resin layer formed on said supporting substrate; and
a transparent electrode formed on said organic resin layer,
wherein said transparent electrode includes
a first layer containing a zinc oxide and formed in close contact with said organic resin layer and
a second layer containing a zinc oxide and which has a thickness thicker than a thickness of said first layer and is formed on said first layer, wherein
said first layer is deposited by either one of a DC sputtering and a DC magnetron sputtering, and
said second layer is deposited by any one of a radio frequency sputtering, a radio frequency magnetron sputtering, a radio frequency superimposing a DC sputtering, and a radio frequency superimposing a DC magnetron sputtering.

2. The display substrate as set forth in claim 1, wherein either gallium or aluminum, or both are doped to said zinc oxide of said first layer and said second layer.

3. The display substrate as set forth in claim 1, wherein said organic resin layer is a color filter layer.

4. The display substrate as set forth in claim 3, wherein a buffer layer consisting of an organic resin is sandwiched between said color filter layer and said transparent electrode, and said transparent electrode is formed in close contact with said buffer layer.

5. The display substrate as set forth in claim 1, wherein said transparent electrode includes a third layer containing a zinc oxide and is formed on said second layer by a DC sputtering or a DC magnetron sputtering.

6. A display substrate comprising:
a supporting substrate;
an organic resin layer formed on said supporting substrate; and
a transparent electrode formed on said organic resin layer, wherein said transparent electrode including:
a first layer containing a zinc oxide and formed in close contact with said organic resin layer; and
a second layer containing a zinc oxide, which has a resistivity lower than a resistivity of said first layer, in which thickness is thicker than a thickness of said first layer, and is formed on said first layer.

7. The display substrate as set forth in claim 6, wherein either gallium or aluminum, or both are doped to said zinc oxide of said first layer and said second layer.

8. The display substrate as set forth in claim 6, wherein the resistivity of said transparent electrode is lower than 4μΩ·m.

9. The display substrate as set forth in claim 6, wherein said organic resin layer includes a color filter layer.

10. The display substrate as set forth in claim 6, wherein a ratio of an Xray diffraction intensity of a (101) surface to an X ray diffraction intensity of a (100) surface is 0.05 or lower.

11. The display substrate as set forth in claim 9, wherein a buffer layer consisting of an organic resin is sandwiched between said color filter layer and said transparent electrode, and said transparent electrode is formed in close contact with said buffer layer.

12. The display substrate as set forth in claim 6, wherein said transparent electrode includes a third layer consisting of a zinc oxide, and which has a resistivity higher than a resistivity of said second layer and is formed on said second layer.

13. The display substrate as set forth in claim 6, wherein an alignment layer is formed on said transparent electrode.

14. The display substrate as set forth in claim 12, wherein a resistivity of said transparent electrode is 7 μΩ·m or lower.

15. The display substrate as set forth in claim 6, wherein a resistivity of said first layer of said transparent electrode is 7 μΩ·m or higher.

16. A display device comprising:
a TFT substrate including an organic resin layer and a first transparent conductive layer formed on said organic resin layer;
a display substrate including a color filter layer formed of an organic resin and a second transparent conductive layer containing a zinc oxide and formed on said color filter layer; and
a display element interposed between said TFT substrate and said display substrate, wherein
at least one of said first transparent conductive layer and said second transparent conductive layer including:
a first layer formed in close contact with one of said organic resin layer and said color filter layer; and
a second layer is formed on said first layer and is thicker than said first layer, wherein
said first layer is formed by either one of a DC sputtering and a DC magnetron sputtering, said second layer is formed by any one of a radio frequency sputtering, a radio frequency magnetron sputtering, a radio frequency superimposing a DC sputtering, and a radio frequency superimposing a DC magnetron sputtering.

17. The display device as set forth in claim 16, wherein said transparent electrode includes a third layer consisting of a zinc oxide formed on said second layer by either one of a DC sputtering and a DC magnetron sputtering.

18. A display device comprising:
a TFT substrate including an organic resin layer and a first transparent conductive layer formed on said organic resin layer;
a display substrate including a color filter layer formed of an organic resin and a second transparent conductive layer containing a zinc oxide and in which thickness is thicker than a thickness of said first transparent conductive layer and is formed on said color filter layer; and
a display element interposed between said TFT substrate and said display substrate, wherein
each of said first transparent conductive layer and said second transparent conductive layer including:
a first layer containing a zinc oxide and formed in close contact with one of said organic resin layer and said color filter layer; and
a second layer containing a zinc oxide, and which has a resistivity lower than a resistivity of said first layer, in which thickness is thicker than a thickness of said first layer, and is formed on said first layer.

19. The display device as set forth in claim 18, wherein said transparent electrode including a zinc oxide third layer formed on said second layer, and a resistivity of said third layer is higher than that of said second layer.

20. The display device as set forth in claim 18, wherein a resistivity of said transparent conductive layer is 7 μΩ·m or lower.

21. The display device as set forth in claim 18, wherein a resistivity of said first layer of said transparent conductive layer is 7 μΩ·m or higher.

22. A method of manufacturing a display substrate comprising:
forming an organic resin layer on a supporting substrate; and
forming a transparent electrode on said organic resin layer, wherein
forming said transparent electrode includes:
forming a first layer containing a zinc oxide in close contact with said organic resin layer by either one of a DC sputtering and a DC magnetron sputtering; and
depositing a second layer containing a zinc oxide on said first layer by one of a radio frequency sputtering, a radio frequency magnetron sputtering, a radio frequency superimposing a DC sputtering, and a radio frequency superimposing a DC magnetron sputtering.

23. The method of manufacturing a display substrate as set forth in claim 22, wherein forming said organic resin layer on said supporting substrate includes forming a color filter layer on said supporting substrate.

24. The method of manufacturing a display substrate as set forth in claim 23, wherein said method further includes forming a buffer layer between said color filter layer and said transparent conductive layer.

25. The method of manufacturing a display substrate as set forth in claim 22, wherein said method further includes forming a third layer containing a zinc oxide on said second layer by DC by either of a sputtering and a DC magnetron sputtering.

26. The method of manufacturing a display substrate as set forth in claim 22, wherein either one of said DC sputtering and said DC magnetron sputtering is performed such that a horizontal component of an incidence angle of particles to said supporting substrate is controlled to remain larger than a vertical one.

27. The method of manufacturing a display substrate as set forth in claim 22, wherein forming said transparent electrode utilizes a target and said supporting substrate and said target is placed relatively concentrically, and a deposition is performed while said supporting substrate is being rotated.

28. The method of manufacturing a display substrate as set forth in claim 22, wherein forming said transparent electrode utilizes a target and includes placing a face of said supporting substrate and that of said target in parallel to each other, and transferring said face of the supporting substrate several times along said front face of the target.
